(19) United States
(12) Patent Application Publication
(10) Pub. No.: US 2026/0066854 A1
(43) Pub. Date: Mar. 5, 2026

(54) BIAS SUPPLY CIRCUIT AND AMPLIFIER CIRCUIT

(71) Applicant: SUMITOMO ELECTRIC DEVICE INNOVATIONS, INC., Kanagawa (JP)

(72) Inventor: Kunihiro USAMI, Kanagawa (JP)

(21) Appl. No.: 19/290,892

(22) Filed: Aug. 5, 2025

(30) Foreign Application Priority Data
Sep. 4, 2024 (JP) 2024-152384

(51) Int. Cl. H03F 3/04; H03F 1/56

(52) U.S. Cl. CPC H03F 3/04; H03F 1/56; H03F 2200/222; H03F 2200/387

(57) ABSTRACT

A bias supply circuit includes a first inductor connected between a bias supply terminal that supplies a bias voltage to an amplifier and a power supply terminal connected to a power supply, a second inductor connected in series with the first inductor between the bias supply terminal and the power supply terminal and connected between the first inductor and the power supply terminal, a first capacitor shunt-connected to a first node between the first inductor and the second inductor, and a second capacitor shunt-connected to a second node between the second inductor and the power supply terminal.

### CROSS REFERENCE TO RELATED APPLICATIONS

This application claims priority based on Japanese Patent Application No. 2024-152384 filed on Sep. 4, 2024, the entire contents of which are incorporated herein by reference.

### BACKGROUND

### 1. Field of the Invention

The present disclosure relates to a bias supply circuit and an amplifier circuit.

### 2. Description of the Related Art

An amplifier circuit includes a bias supply circuit that supplies a bias voltage to an amplifier such as a transistor. It is known that a surge voltage generated in a power conversion circuit such as an inverter is reduced by using an inductor (for example, PTL 1: Japanese Unexamined Patent Application Publication No. 2009-71982 and PTL 2: Japanese Unexamined Patent Application Publication No. 11-262247).

### SUMMARY

A bias supply circuit according to an embodiment of the present disclosure includes a first inductor connected between a bias supply terminal configured to supply a bias voltage to an amplifier and a power supply terminal connected to a power supply, a second inductor connected in series with the first inductor between the bias supply terminal and the power supply terminal and connected between the first inductor and the power supply terminal, a first capacitor shunt-connected to a first node between the first inductor and the second inductor, and a second capacitor shunt-connected to a second node between the second inductor and the power supply terminal.

### BRIEF DESCRIPTION OF THE DRAWINGS

FIG. 1 is a block diagram of an amplifier circuit according to a first embodiment.

FIG. 2 is a circuit diagram of a bias supply circuit in the first embodiment.

FIG. 3 is a circuit diagram of a bias supply circuit according to a first comparative example.

FIG. 4 is a schematic diagram illustrating voltage, input power, and output power versus time in the first comparative example.

FIG. 5 is a diagram illustrating output power versus time in the first comparative example.

FIG. 6 is a circuit diagram of a bias supply circuit according to a second comparative example.

FIG. 7 is a schematic diagram illustrating voltage versus time in the second comparative example.

FIG. 8 is a circuit diagram of a bias supply circuit according to a third comparative example.

FIG. 9 is a schematic diagram illustrating voltage versus time in the third comparative example.

FIG. 10 is a diagram illustrating output power versus time in the third comparative example.

FIG. 11 is a circuit diagram of a bias supply circuit according to a fourth comparative example.

FIG. 12 is a schematic diagram illustrating voltage versus time in the fourth comparative example.

FIG. 13 is a diagram illustrating output power versus time in the fourth comparative example.

FIG. 14 is a schematic diagram illustrating voltage versus time in the first embodiment.

FIG. 15 is a diagram illustrating output power versus time in the first embodiment.

FIG. 16 is a circuit diagram of a bias supply circuit according to a second embodiment.

FIG. 17 is a schematic diagram illustrating voltage versus time in the second embodiment.

FIG. 18 is a circuit diagram of a bias supply circuit according to a third embodiment.

FIG. 19 is a plan view of an amplifier circuit according to a fourth embodiment.

### DETAILED DESCRIPTION

A rapid increase in the input power of an amplifier circuit may cause a rapid increase in output power followed by a transient decrease in output power. The transient change in output power is not sufficiently small even when inductors such as those disclosed in PTL 1 and PTL 2 are used.

An object of the present disclosure is to provide a bias supply circuit and an amplifier circuit that can reduce a transient change in output power.

### Description of Embodiments of the Present Disclosure

First, embodiments of the present disclosure will be listed and described.
(1) A bias supply circuit according to an embodiment of the present disclosure includes a first inductor connected between a bias supply terminal configured to supply a bias voltage to an amplifier and a power supply terminal connected to a power supply, a second inductor connected in series with the first inductor between the bias supply terminal and the power supply terminal and connected between the first inductor and the power supply terminal, a first capacitor shunt-connected to a first node between the first inductor and the second inductor, and a second capacitor shunt-connected to a second node between the second inductor and the power supply terminal. This can reduce a transient change in output power.
(2) In the above (1), the bias supply terminal may be connected to a node between an output end of the amplifier and an output terminal that outputs a high frequency signal amplified by the amplifier. The bias supply circuit may include, between the bias supply terminal and the first inductor, a circuit configured to reduce a leakage of the high frequency signal to the power supply terminal. This can reduce the influence of the first inductor, the second inductor, and the first capacitor on the high frequency signal output by the amplifier.
(3) In the above (1) or (2), the bias supply circuit may further include a first resistor connected in parallel with the first inductor between the bias supply terminal and the first node, and a second resistor connected in parallel with the second inductor between the first node and the second node. This can reduce a decrease in bias voltage.
(4) In any one of the above (1) to (3), the first capacitor may have a capacitance value smaller than a capacitance value of the second capacitor. This can reduce a transient change in output power.
(5) In any one of the above (1) to (4), the first inductor may have an inductance smaller than an inductance of the second inductor. This can reduce a transient change in output power.
(6) In any one of the above (1) to (5), the bias supply circuit may further include a third inductor connected in series with each of the first inductor and the second inductor between the bias supply terminal and the power supply terminal and connected between the first node and the second inductor, and a third capacitor shunt-connected to a third node between the third inductor and the second inductor. This can reduce a transient change in output power.
(7) In the above (6), the bias supply circuit may further include a first resistor connected in parallel with the first inductor between the bias supply terminal and the first node, a second resistor connected in parallel with the second inductor between the third node and the second node, and a third resistor connected in parallel with the third inductor between the first node and the third node. This can reduce a decrease in bias voltage.
(8) An amplifier circuit according to an embodiment of the present disclosure includes the bias supply circuit according to any one of the above (1) to (7) and the amplifier. This can reduce a transient change in output power of the amplifier circuit.
(9) In the above (8), the amplifier may be configured to perform a pulsed operation. This can reduce a change in output power when the output power is likely to change.
(10) In the above (8) or (9), the amplifier may have a maximum output power of 100 W or more. This can reduce a change in output power when the output power is likely to change.

### Details of Embodiments of the Present Disclosure

Specific examples of a bias supply circuit and an amplifier circuit according to an embodiment of the present disclosure will be described below with reference to the drawings. The present disclosure is not limited to these examples, but is defined by the scope of the claims, and is intended to include all modifications within the scope and meaning equivalent to the scope of the claims.

### First Embodiment

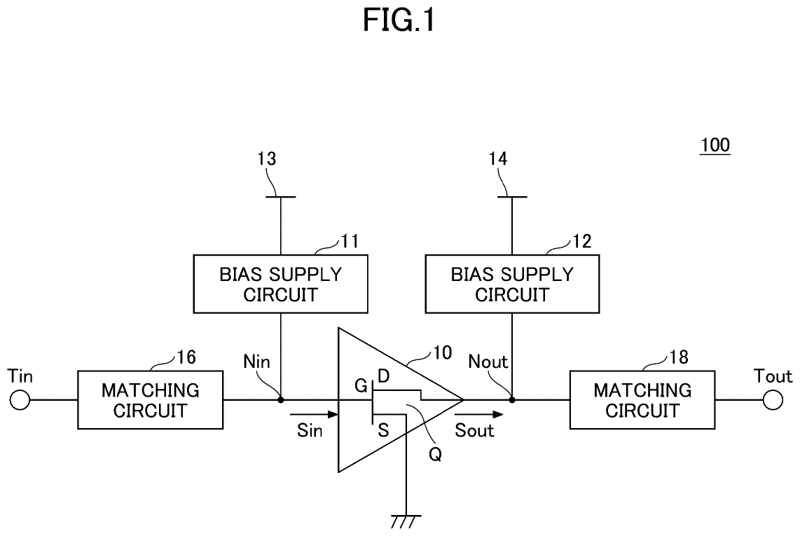

FIG. 1 is a block diagram of an amplifier circuit according to a first embodiment. As illustrated in FIG. 1, an amplifier circuit 100 includes an amplifier 10, bias supply circuits 11 and 12, matching circuits 16 and 18, an input terminal Tin, and an output terminal Tout.

The amplifier 10 amplifies an input signal Sin input from the input terminal Tin via the matching circuit 16, and outputs the amplified signal as an output signal Sout to the output terminal Tout via a matching circuit 18. The input signal Sin and the output signal Sout are high frequency signals, for example, microwaves (with a frequency of 300 MHz to 30 GHz) or millimeter waves (with a frequency of 30 GHz to 300 GHz).

The amplifier 10 includes, for example, a transistor Q. The transistor Q is, for example, a field effect transistor (FET), and includes a source S, a gate G, and a drain D. The source S is grounded. The input signal Sin is input to the gate G. The output signal Sout is output from the drain D. The transistor Q is, for example, a gallium nitride high electron mobility transistor (GaN HEMT).

The matching circuit 16 matches an impedance as viewed from the input terminal Tin to the matching circuit 16 with an impedance as viewed from the matching circuit 16 to the amplifier 10. The matching circuit 18 matches an impedance as viewed from the amplifier 10 to the matching circuit 18 with an impedance as viewed from the matching circuit 18 to the output terminal Tout. The node Nin is a node between the matching circuit 16 and the amplifier 10. The node Nout is a node between the amplifier 10 and the matching circuit 18. The bias supply circuit 11 supplies a gate bias voltage from a power supply 13 to the node Nin, and reduces the leakage of the input signal Sin passing through the node Nin to the power supply 13. The bias supply circuit 12 supplies a drain bias voltage from a power supply 14 to the node Nout, and reduces the leakage of the input signal Sin passing through the node Nout to the power supply 13.

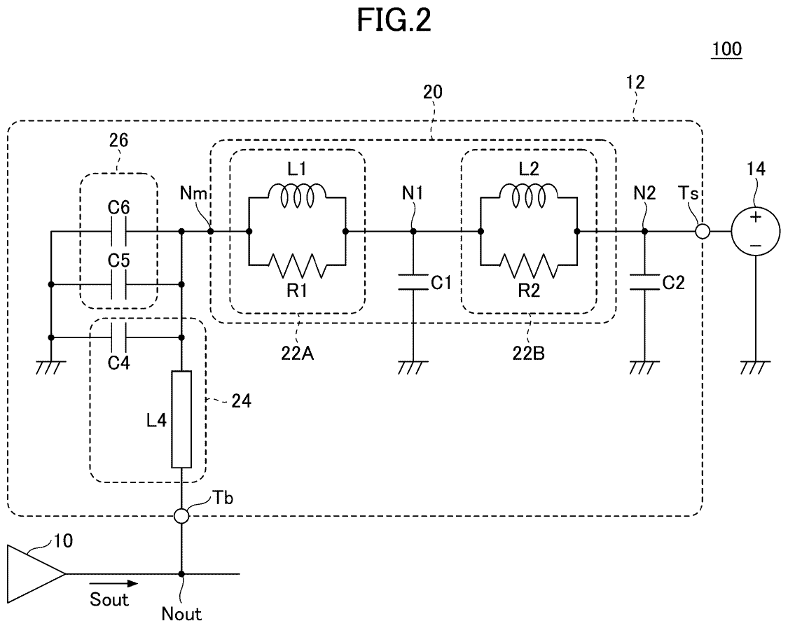

FIG. 2 is a circuit diagram of a bias supply circuit in the first embodiment. As illustrated in FIG. 2, the bias supply circuit 12 includes circuits 20, 24, and 26, a capacitor C2, a power supply terminal Ts, and a bias supply terminal Tb. The power supply terminal Ts is electrically connected to the power supply 14, and is supplied with a power supply voltage. The bias supply terminal Tb is electrically connected to the node Nout and supplies a bias voltage to the amplifier 10.

The circuit 20 includes parallel circuits 22A and 22B and a capacitor C1. The parallel circuit 22A includes an inductor L1 and a resistor R1 that are connected in parallel with each other between the node Nm and a node N1. The parallel circuit 22B includes an inductor L2 and a resistor R2 that are connected in parallel with each other between the nodes N1 and N2. The capacitor C1 is shunt-connected to the node N1. The capacitor C2 is shunt-connected to a node N2 between the circuit 20 and the power supply terminal Ts.

A circuit 24 includes a line L4 and a capacitor C4. A first end and a second end of the line L4 are electrically connected to the bias supply terminal Tb and the node Nm, respectively. The first end of the capacitor C4 is electrically connected to a node between the line LA and the node Nm. The second end of the capacitor C4 is electrically connected to the ground. The line L4 is, for example, a λ/4 line having a length of approximately λ/4, where λ is a wavelength corresponding to the center frequency of an operating band of the amplifier 10. The length of the line L4 may be, for example, greater than λ/8 and less than 3λ/8, or may be 3λ/16 to 5λ/16. The circuit 24 reduces the leakage of the output signal Sout to the power supply 14.

A circuit 26 has capacitors C5 and C6. The capacitors C5 and C6 are connected in parallel with each other between the node Nm and the ground. The capacitance values of the capacitors C5 and C6 are greater than the capacitance value of the capacitor C4. The circuit 26 passes to the ground a signal in the output signal Sout whose frequency is lower than the operating band of the amplifier 10. The circuit 26 is not necessarily provided.

### First Comparative Example

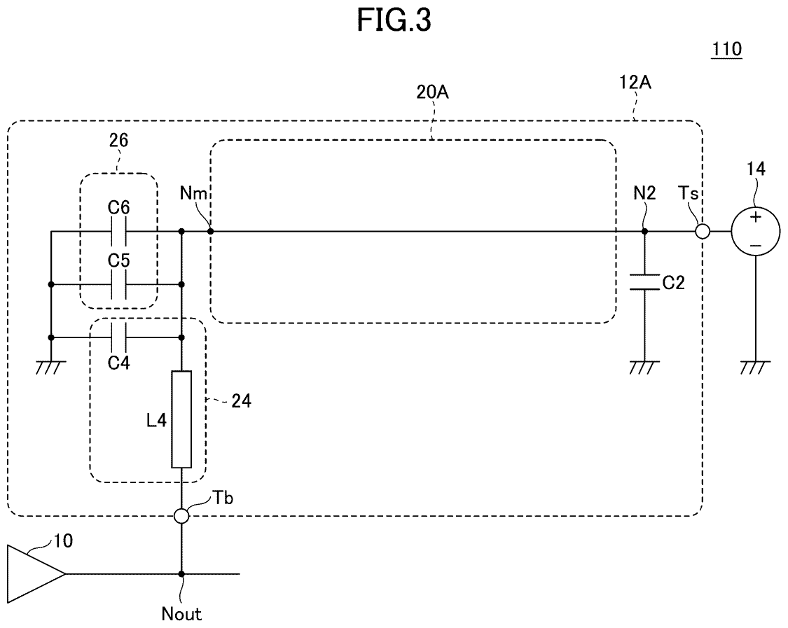

A comparative example will be described to describe the operation of the circuit 20. FIG. 3 is a circuit diagram of a bias supply circuit according to a first comparative example. As illustrated in FIG. 3, a bias supply circuit 12A of an amplifier circuit 110 according to the first comparative example does not include an inductor or a capacitor in a circuit 20A. The node Nm and the node N2 are electrically connected to each other.

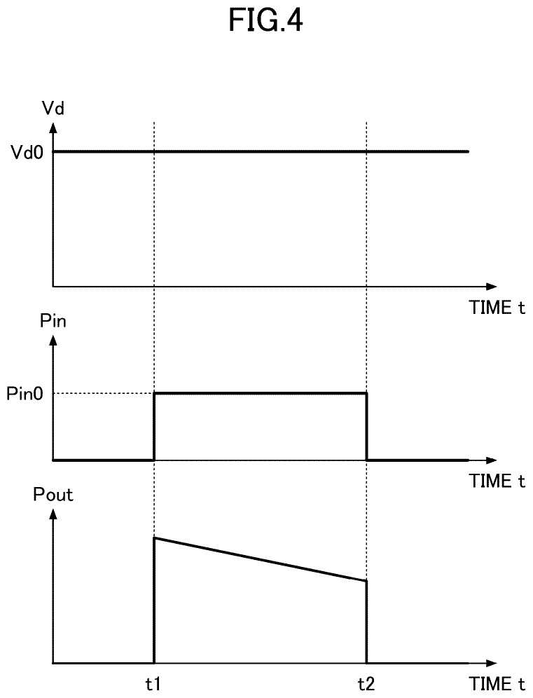

FIG. 4 is a schematic diagram illustrating voltage, input power, and output power versus time in the first comparative example. In FIG. 4, the horizontal axes each represent time t, and the vertical axes each represent a voltage Vd at the node Nm in FIG. 3, an input power Pin of the input signal Sin, and an output power Pout of the output signal Sout.

As illustrated in FIG. 4, the input power Pin is small and the output power Pout is also small in a period until the time t1. The voltage Vd is a voltage Vd0. The capacitor C2 is charged. In a period between the time t1 and the time t2, the input signal Sin with the power Pin0 is input as the input power Pin. The output power Pout increases at the time t1, but gradually decreases toward the time t2. As described above, when a pulsed power is input as the input power Pin, the output power Pout varies. This is because the temperature of the amplifier 10 rises when the amplifier 10 amplifies the input power Pin. As the temperature of the amplifier 10 rises, the power gain of the amplifier 10 decreases, and the output power Pout decreases. As the output power Pout increases, a current is supplied from the bias supply circuit 12A to the amplifier 10. When the current rapidly increases, the current supplied from the power supply 14 is limited, but a current is supplied from the capacitor C2 in addition to the power supply 14, and thus the voltage Vd is substantially constant at the voltage Vd0 in the period between the time t1 and the time t2.

A GaN HEMT for 800 W was used as the amplifier 10, and the output power Pout was measured when the input signal Sin having a frequency of 3 GHZ and a pulse width of 200 μsec was input. The capacitance values of the capacitors C2, C4, C5, and C6 are 1000 μF, 10 μF, 1000 μF, and 0.22 μF, respectively. The voltage Vd0 is 50 V.

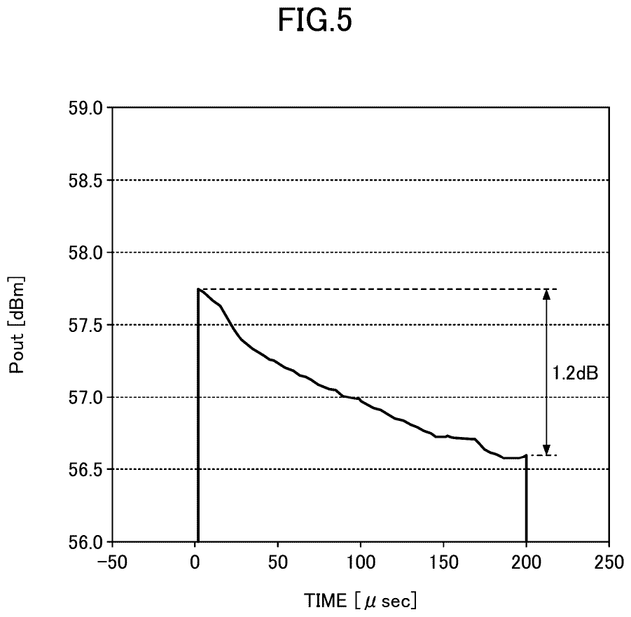

FIG. 5 is a diagram illustrating output power versus time in the first comparative example. The power Pin0 illustrated in FIG. 4 is applied during a period from 0 μsec to 200 μsec. As illustrated in FIG. 5, the output power Pout is approximately 57.75 dBm at 0 μsec, but the output power Pout is approximately 56.6 dBm at 200 μsec. The difference between the maximum and minimum values of the output power Pout between 0 μsec and 200 μsec is approximately 1.2 dB. As described above, in the first comparative example, the variation in the output power Pout is large.

### Second Comparative Example

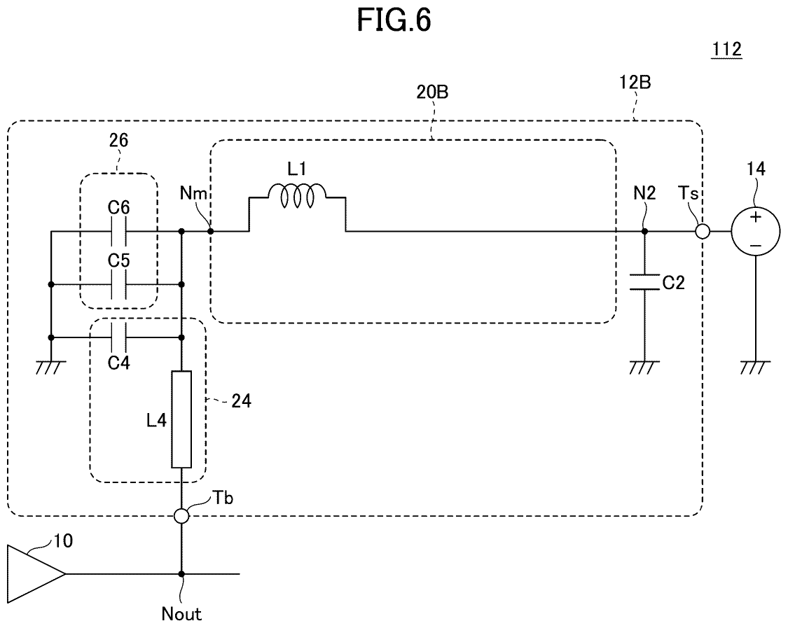

FIG. 6 is a circuit diagram of a bias supply circuit according to a second comparative example. As illustrated in FIG. 6, a bias supply circuit 12B of an amplifier circuit 112 according to the second comparative example includes the inductor L1 in a circuit 20B. The first end and the second end of the inductor L1 are connected to the node Nm and the node N2, respectively. The other configurations are the same as those of the first comparative example, and the description thereof will be omitted.

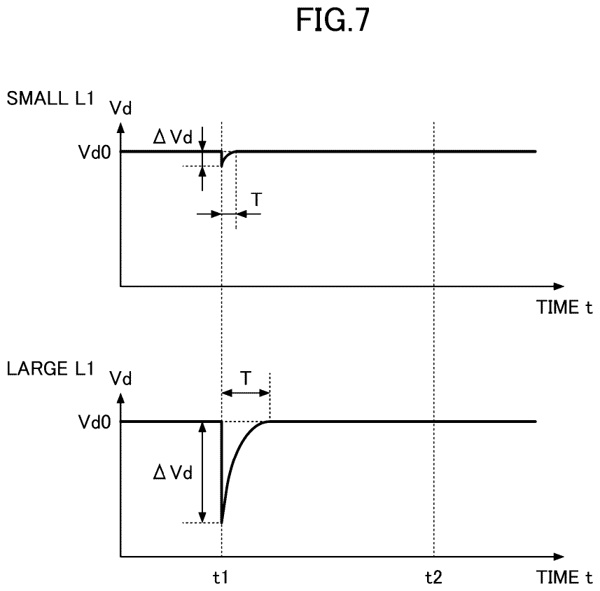

FIG. 7 is a schematic diagram illustrating voltage versus time in the second comparative example. In FIG. 7, “small L1” denotes a case where the inductance of the inductor L1 is small, and “large L1” denotes a case where the inductance of the inductor L1 is large.

When the input power Pin increases at the time t1, a current is rapidly supplied from the bias supply circuit 12B to the amplifier 10, and a current flowing through the inductor L1 increases. When the current flowing through the inductor L1 is denoted as I, a counter electromotive force of Vd′=−L1 (dI/dt) is generated, where L1 is the inductance of the inductor. As a result, as illustrated in FIG. 7, the voltage Vd decreases at the time t1, and then the voltage Vd gradually returns to the voltage Vd0. When the inductance of the inductor L1 is small, the amount of decrease ΔVd in the voltage Vd from the voltage Vd0 is small. Since a time constant of the voltage Vd is small, a period T in which the voltage Vd returns to the voltage Vd0 is short. When the inductance of the inductor L1 is large, the amount of decrease ΔVd in the voltage Vd from the voltage Vd0 is large. Since the time constant of the voltage Vd is large, the period T in which the voltage Vd returns to the voltage Vd0 is long. As described above, when the period T during which the voltage Vd is decreased below the voltage Vd0 is made longer, the amount of decrease ΔVd in the voltage Vd increases.

### Third Comparative Example

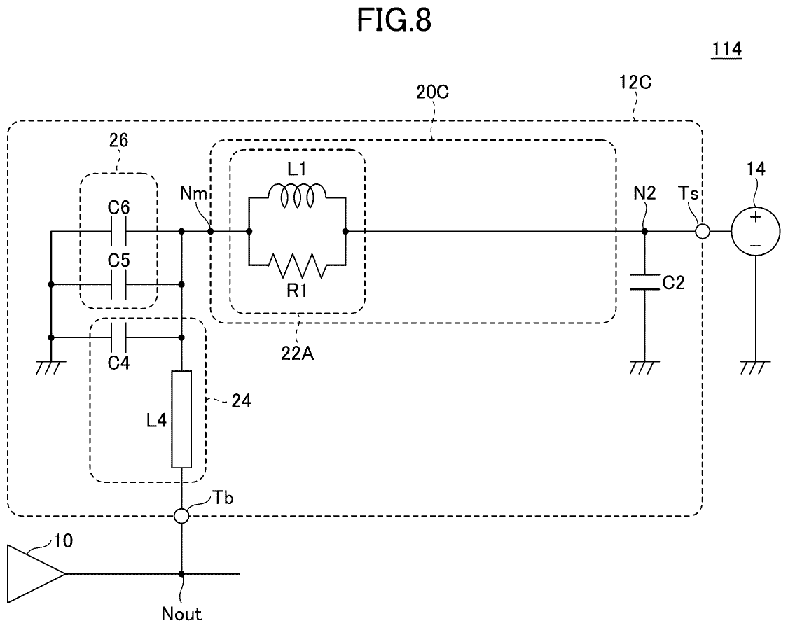

FIG. 8 is a circuit diagram of a bias supply circuit according to a third comparative example. As illustrated in FIG. 8, a bias supply circuit 12C of an amplifier circuit 114 according to the third comparative example includes the parallel circuit 22A in a circuit 20C. The parallel circuit 22A includes the inductor L1 and the resistor R1 that are connected in parallel with each other. The other configurations are the same as those of the second comparative example, and the description thereof will be omitted.

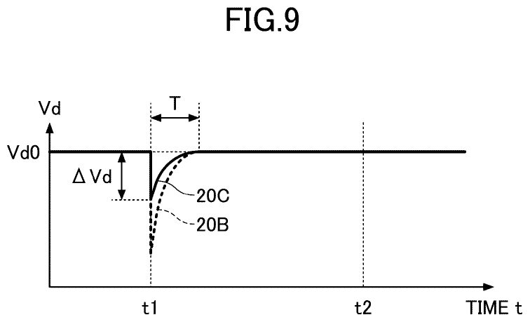

FIG. 9 is a schematic diagram illustrating voltage versus time in the third comparative example. In FIG. 9, the reference numerals 20B and 20C represent the second comparative example and the third comparative example, respectively. In the circuit 20C of the third embodiment, the amount of decrease ΔVd in the voltage Vd at the time t1 can be made smaller than that in the circuit 20B of the second embodiment. This is because a current flows through the resistor R1 in parallel with the inductor L1 at the time t1.

In the third comparative example, the output power Pout was measured. The capacitance values of the capacitors C2, C4, C5, and C6 were set to the same values as those of the first comparative example illustrated in FIG. 5, and the inductance of the inductor L1 and the resistance value of the resistor R1 were set to 10 pH and 0.5Ω, respectively.

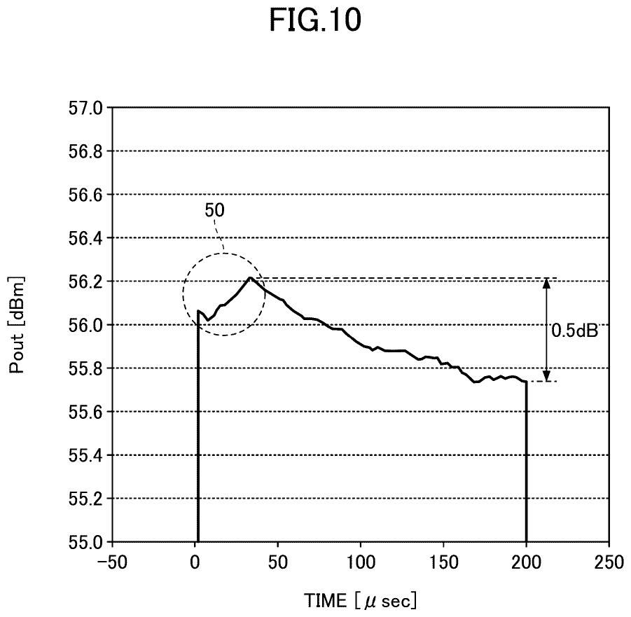

FIG. 10 is a diagram illustrating output power versus time in the third comparative example. As illustrated in FIG. 10, the output power Pout is lower than that of the first comparative example illustrated in FIG. 5 in a range 50 of 0 μsec to 40 μsec. This is because the voltage Vd becomes lower than the voltage Vd0 after the time t1, as illustrated in FIG. 9. However, at 40 μsec or more, the decrease in the output power Pout is substantially the same as that of the first comparative example in FIG. 5. The difference between the maximum and minimum values of the output power Pout between 0 μsec and 200 μsec is approximately 0.5 dB. The reason for the large variation in the output power Pout at 40 μsec or more is that the period T is short as illustrated in FIG. 9.

### Fourth Comparative Example

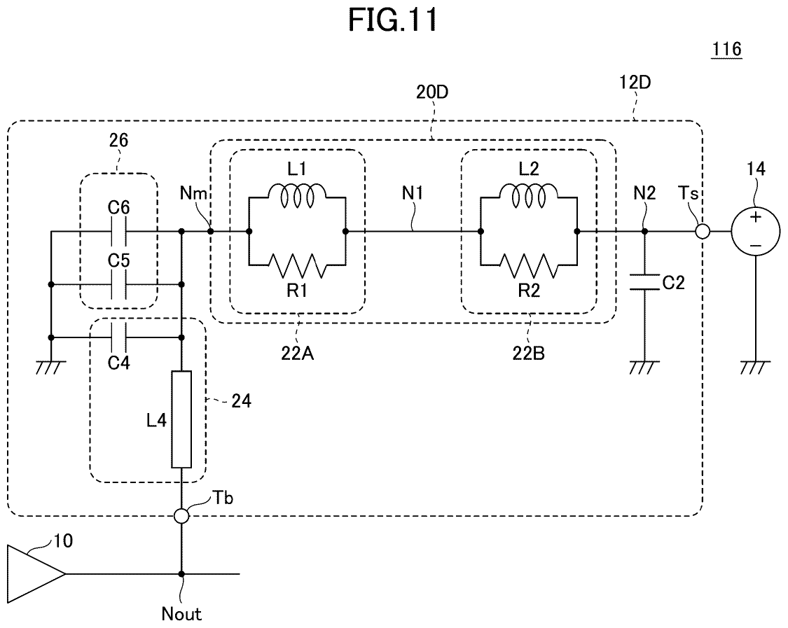

FIG. 11 is a circuit diagram of a bias supply circuit according to a fourth comparative example. As illustrated in FIG. 11, in a bias supply circuit 12D of an amplifier circuit 116 according to the fourth comparative example, a circuit 20D includes the parallel circuits 22A and 22B. The parallel circuits 22A and 22B are connected in series with each other between the node Nm and the node N2. The parallel circuit 22B includes the inductor L2 and the resistor R2 that are connected in parallel with each other. The other configurations are the same as those of the third comparative example, and the description thereof will be omitted.

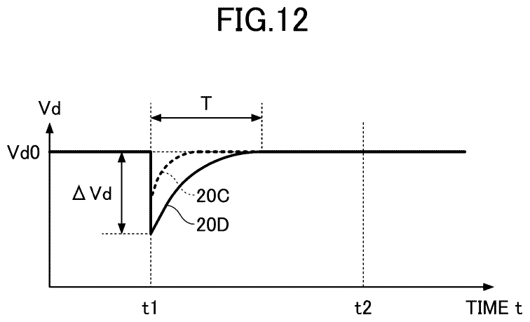

FIG. 12 is a schematic diagram illustrating voltage versus time in the fourth comparative example. In FIG. 12, reference numerals 20C and 20D represent the third comparative example and the fourth comparative example, respectively. In the circuit 20D of the fourth comparative example, the period T during which the voltage Vd decreases below the voltage Vd0 can be made longer than that in the circuit 20C of the third comparative example. However, when a current starts to flow through the parallel circuit 22A at the time t1, the current is supplied from the capacitor C2 and the power supply 14, and thus the current also starts to flow through the parallel circuit 22B. Thus, the amount of decrease ΔVd in the voltage Vd from the voltage Vd0 increases due to a counter electromotive force by the parallel circuit 22A and a counter electromotive force by the parallel circuit 22B.

In the fourth comparative example, the output power Pout was measured. The capacitance values of the capacitors C2, C4, C5, and C6 were set to the same as those of the first comparative example illustrated in FIG. 5, and the inductance of the inductor L1 and the resistance value of the resistor R1 were set to 4.7 pH and 0.5Ω, respectively. The inductance of the inductor L2 and the resistance value of the resistor R2 were set to 10 μH and 0.5Ω, respectively.

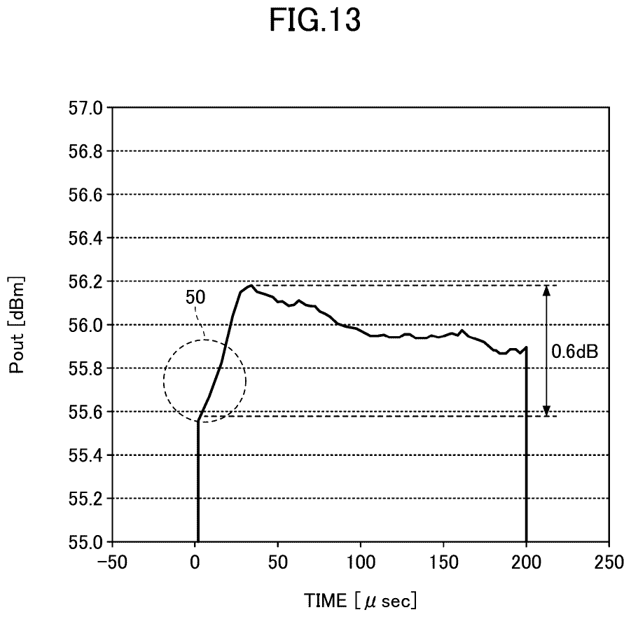

FIG. 13 is a diagram illustrating output power versus time in the fourth comparative example. As illustrated in FIG. 13, the variation in the output power Pout after 40 μsec is smaller than those of the first comparative example in FIG. 5 and the third comparative example in FIG. 10. However, between the time of 0 μsec and the time of 20 μsec, as indicated by the range 50, the output power Pout is lower than the output power Pout at 200 μsec. Thus, the difference between the maximum and minimum values of the output power Pout between 0 μsec and 200 μsec is approximately 0.6 dB, which is larger than that of the third comparative example in FIG. 10. This is because the amount of decrease ΔVd in the voltage Vd is large as illustrated in FIG. 12.

### Description of First Embodiment

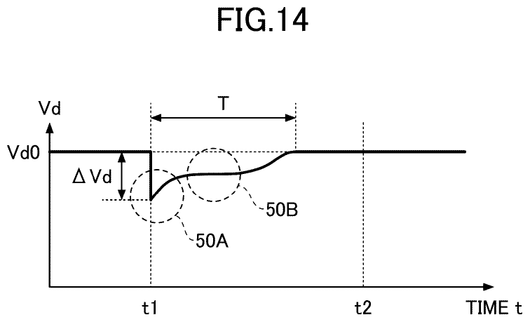

FIG. 14 is a schematic diagram illustrating voltage versus time in the first embodiment. In FIG. 14, the capacitors C1 and C2 are charged by the time t1. At the time t1, a current is rapidly supplied from the bias supply circuit 12 to the amplifier 10. In the range 50A indicated by a dashed line circle, a current flows mainly from the capacitor C1 to the parallel circuit 22A. By reducing the inductance of the inductor L1, the counter electromotive force of the parallel circuit 22A can be reduced. The capacitor C1 slows down the decrease in the voltage at the node N1 compared to the fourth comparative example. When the voltage at node N1 begins to drop, a current flows from capacitor C2 to parallel circuit 22B in the range 50B. The voltage Vd becomes lower than the voltage Vd0 due to the counter electromotive force of the parallel circuit 22B. In this manner, by providing the capacitor C1, a time difference occurs between the currents flowing through the parallel circuits 22A and 22B, and thus the period T during which the voltage Vd is decreased below the voltage Vd0 can be made longer.

In the first embodiment, the output power Pout was measured. The capacitance values of the capacitors C2, C4, C5, and C6 were the same as those of the first comparative example illustrated in FIG. 5, the capacitance value of the capacitor C1 was set to 120 μF, and the inductance of the inductor L1 and the resistance value of the resistor R1 were set to 4.7 μH and 0.5Ω, respectively. The inductance of the inductor L2 and the resistance value of the resistor R2 were set to 10 μH and 0.5Ω, respectively.

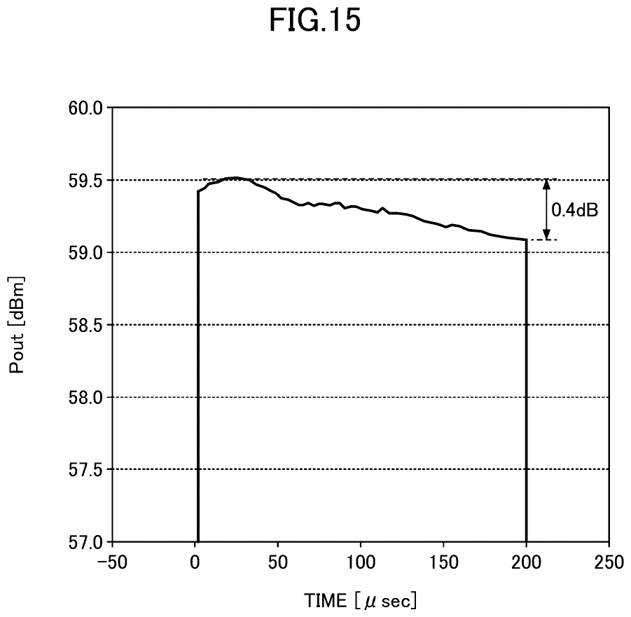

FIG. 15 is a diagram illustrating output power versus time in the first embodiment. As illustrated in FIG. 15, the decrease in the output power Pout near 0 μsec is smaller than that of the fourth comparative example in FIG. 13. The variation in the output power Pout after the time of 40 μsec is smaller than those of the first comparative example in FIG. 5 and the third comparative example in FIG. 10. Thus, the difference between the maximum and minimum values of the output power Pout between 0 μsec and 200 μsec is approximately 0.4 dB, which is smaller than those of the first comparative example, the third comparative example, and the fourth comparative example. This is because the amount of decrease ΔVd in the voltage Vd can be appropriately reduced and the period T during which the voltage Vd is decreased below the voltage Vd0 can be appropriately made longer in FIG. 14. As described above, in the first embodiment, the transient phenomenon of the output power Pout can be reduced by appropriately setting the capacitance values of the capacitors C1 and C2, the inductances of the inductors L1 and L2, and the resistance values of the resistors R1 and R2.

### Second Embodiment

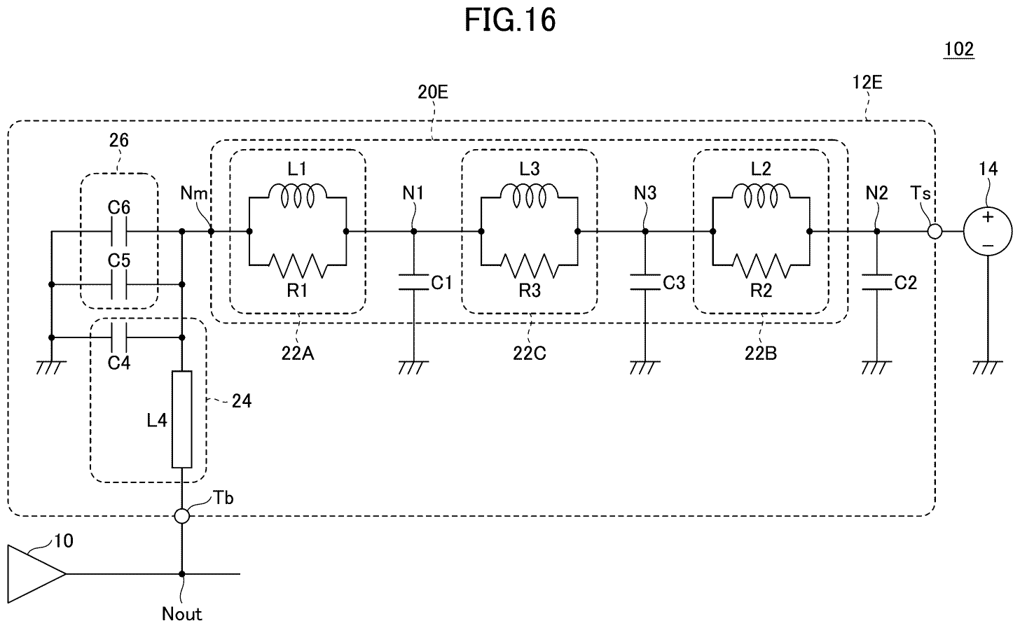

FIG. 16 is a circuit diagram of a bias supply circuit according to a second embodiment. As illustrated in FIG. 16, in a bias supply circuit 12E of the amplifier circuit 102 according to the second embodiment, a circuit 20E includes parallel circuits 22A, 22B, and 22C. The parallel circuit 22C is connected in series with the parallel circuits 22A and 22B between the node Nm and the node N2, and is connected between the parallel circuits 22A and 22B. The parallel circuit 22C includes an inductor L3 and a resistor R3 that are connected in parallel with each other. A capacitor C3 is shunt-connected to a node N3 between the parallel circuits 22C and 22B. The other configurations are the same as those of the first embodiment, and the description thereof will be omitted.

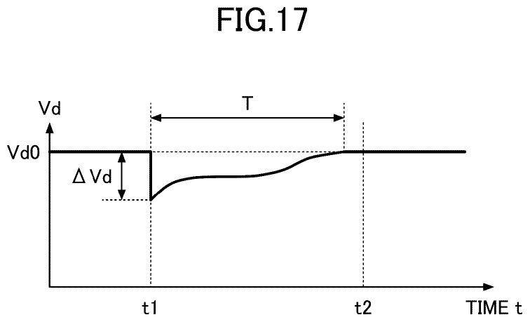

FIG. 17 is a schematic diagram illustrating voltage versus time in the second embodiment. As illustrated in FIG. 17, by connecting the parallel circuits 22A to 22C in series, the period T during which the voltage Vd is decreased below the voltage Vd0 can be made longer than that of the first embodiment in FIG. 14. As described in the second embodiment, three or more parallel circuits may be provided, and three or more capacitors may be provided.

### Third Embodiment

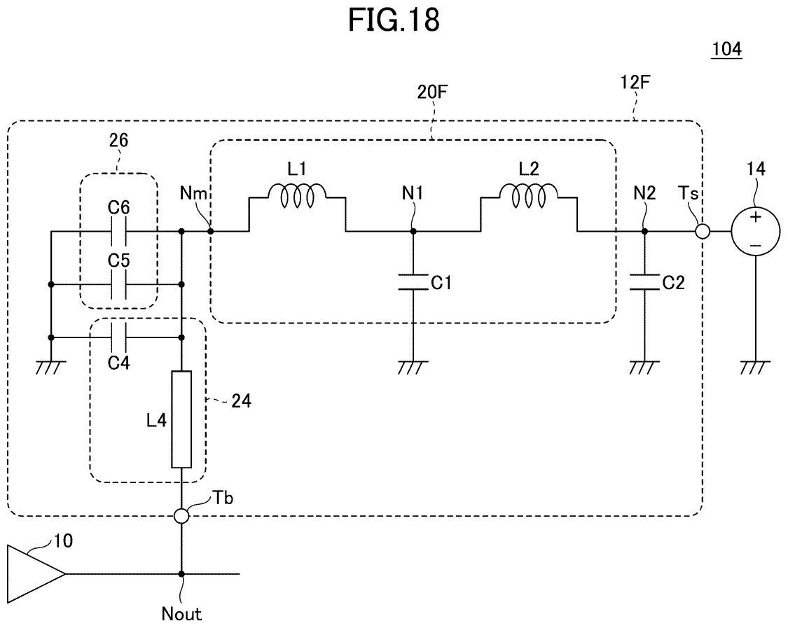

FIG. 18 is a circuit diagram of a bias supply circuit according to a third embodiment. As illustrated in FIG. 18, in a bias supply circuit 12F of an amplifier circuit 104 according to the third embodiment, a circuit 20F includes inductors L1 and L2 and a capacitor C1, but includes no resistors R1 and R2. The other configurations are the same as those of the first embodiment, and the description thereof will be omitted. As described in the third embodiment, when the amount of decrease in the voltage Vd from the voltage Vd0 is appropriate, at least one of the resistor R1 or the resistor R2 may be omitted. In the second embodiment, at least one of the resistors R1 to R3 that are connected between the node Nm and the node N2 may be omitted.

### Fourth Embodiment

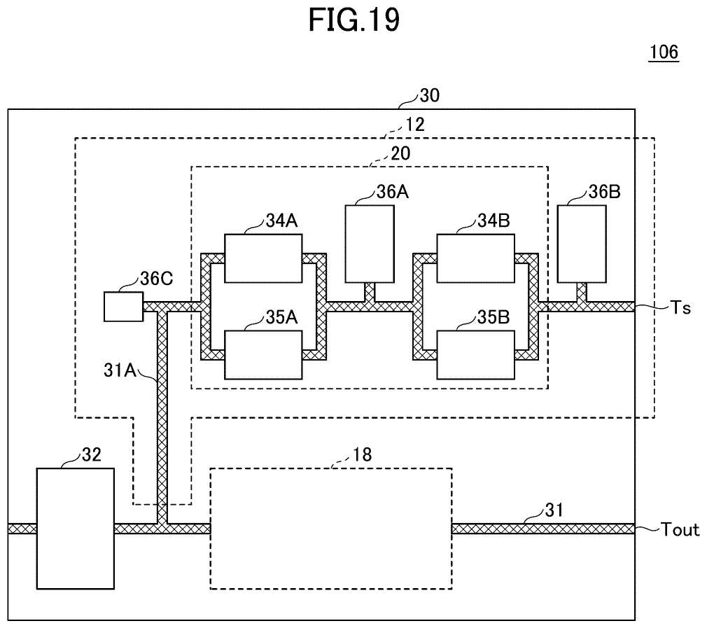

A fourth embodiment is an example in which the bias supply circuit of the first embodiment is provided on a board. FIG. 19 is a plan view of an amplifier circuit according to the fourth embodiment. As illustrated in FIG. 19, an amplifier circuit 106 according to the fourth embodiment includes a board 30, a semiconductor component 32, inductor components 34A and 34B, resistor components 35A and 35B, capacitor components 36A, 36B, and 36C, a line 31, and the matching circuit 18.

The board 30 is an insulating board such as a glass epoxy resin board or a ceramic board. The semiconductor component 32, the inductor components 34A and 34B, the resistor components 35A and 35B, and the capacitor components 36A, 36B, and 36C are mounted on the board 30. The semiconductor component 32 corresponds to the amplifier 10 including a transistor. The inductor components 34A and 34B correspond to inductors L1 and L2, respectively. The resistor components 35A and 35B correspond to the resistors R1 and R2, respectively. The capacitor components 36A, 36B, and 36C correspond to the capacitors C1, C2, and C4, respectively. The line 31 is a metal layer formed on the board 30, and electrically connects the semiconductor component 32, the inductor components 34A and 34B, the resistor components 35A and 35B, and the capacitor components 36A, 36B, and 36C to each other. A line 31A, which is a part of the line 31, corresponds to the line L4.

The bias supply circuit 12 includes the circuit 20, the capacitor components 36B and 36C, the line 31A, and the power supply terminal Ts. The circuit 20 includes the inductor components 34A and 34B, the resistor components 35A and 35B, and the capacitor component 36A. As in the fourth embodiment, the bias supply circuits of the first embodiment to the third embodiment may be provided on the board 30.

According to the first embodiment to the fourth embodiment, as illustrated in FIG. 2 and FIG. 18, the inductor L1 (first inductor) is connected between the bias supply terminal Tb and the power supply terminal Ts. The inductor (second inductor) is connected in series with the inductor L1 between the bias supply terminal Tb and the power supply terminal Ts, and is connected between the inductor L1 and the power supply terminal Ts. The capacitor C1 (first capacitor) is shunt-connected to the node N1 (first node) between the inductors L1 and L2. The capacitor C2 (second capacitor) is shunt-connected to the node N2 (second node) between the inductor L2 and the power supply terminal Ts. As a result, as illustrated in FIG. 14, when the input power Pin of the input signal Sin is rapidly increased, the voltage Vd is decreased, and then the voltage Vd is gradually returned to the voltage Vd0. Thus, even when the temperature of the amplifier 10 rises, the transient change in the output power Pout can be reduced. By appropriately setting the capacitance values of the capacitors C1 and C2 and the inductances of the inductors L1 and L2, optimization to reduce the variation in the output power Pout is performed more easily than in the first comparative example to the fourth comparative example.

As illustrated in FIG. 1 and FIG. 2, the bias supply terminal Tb is connected to a node between the output end of the amplifier 10 and the output terminal Tout. The circuit 24 is provided between the bias supply terminal Tb and the inductor L1, and reduces a leakage of a high frequency signal to the power supply terminal Ts. This can reduce the influence of the inductors L1 and L2 and the capacitor C1 on the high frequency signal output by the amplifier circuit 100.

As illustrated in FIG. 2, the resistor R1 (first resistor) is connected in parallel with the inductor L1 between the bias supply terminal Tb and the node N1. The resistor R2 (second resistor) is connected in parallel with the inductor L2 between the node N1 and the node N2. This can reduce a decrease in the voltage Vd from the voltage Vd0.

In the range 50A in FIG. 14, a current is supplied from the capacitor C1 to the inductor L1, and in the range 50B, a current is supplied from the capacitor C2 to the inductors L1 and L2. From this point of view, the capacitance value of the capacitor C1 may be smaller than the capacitance value of the capacitor C2. The capacitance value of the capacitor C1 may be less than or equal to a half of the capacitance value of the capacitor C2, and may be less than or equal to one-fifth of the capacitance value of the capacitor C2.

From the viewpoint of reducing the decrease in the voltage Vd from the voltage Vd0 in the range 50A, the inductance of the inductor L1 may be smaller than the inductance of the inductor L2. The inductance of the inductor L1 may be less than or equal to three-fourths of the inductance of the inductor L2, or may be less than or equal to a half of the inductance of the inductor L2.

The capacitance value of the capacitor C1 may be greater than the capacitance value of the capacitor C2, and the inductance of the inductor L1 may be greater than the inductance of the inductor L2.

As illustrated in FIG. 16 of the second embodiment, the inductor L3 (third inductor) is connected in series with the inductors L1 and L2 between the bias supply terminal Tb and the power supply terminal Ts, and is connected between the node N1 and the inductor L2. The capacitor C3 (third capacitor) is shunt-connected to the node N3 (third node) between the inductors L3 and L2. This can extend the period T during which the voltage Vd is decreased below the voltage Vd0, as illustrated in FIG. 17. Thus, even when the pulse width of the input signal Sin is large, the variation in the output power Pout can be reduced.

The resistor R3 (third resistor) is connected in parallel with the inductor L3 between the nodes N1 and N3. This can reduce the decrease in the voltage Vd from the voltage Vd0.

The capacitance value of the capacitor C1 and the capacitance value of the capacitor C3 may be smaller than the capacitance value of the capacitor C2. In addition, the inductance of the inductor L1 and the inductance of the inductor L3 may be smaller than the inductance of the inductor L2.

The capacitance values of the capacitors C1 and C3 are, for example, 10 μF to 500 μF. The capacitance value of the capacitor C2 is, for example, 100 μF to 5000 μF. The inductances of the inductors L1 to L3 are, for example, 0.1 μH to 100 μH. The resistance values of the resistors R1 to R3 are, for example, 0.05Ω to 10Ω. The capacitance values of the capacitors C1 to C3, the inductances of the inductors L1 to L3, and the resistance values of the resistors R1 to R3 can be designed as appropriate so that the variation in the output power Pout is reduced.

As illustrated in FIG. 4, when the amplifier 10 performs a pulsed operation, the output power Pout tends to vary. Thus, the inductors L1 and L2 and the capacitors C1 and C2 are provided. A rise time of the input power when the amplifier 10 performs the pulsed operation is, for example, 10 μsec or less. A pulse width is, for example, 50 μsec to 5 msec.

When the output power Pout of the amplifier 10 is large, the amplifier 10 generates heat, and the output power Pout tends to vary. Thus, when the maximum output power of the amplifier 10 is equal to or higher than 100 W, 200 W, or 500 W, the inductors L1 and L2 and the capacitors C1 and C2 are provided.

The embodiments disclosed herein are to be considered as illustrative and non-restrictive in all respects. The scope of the present disclosure is defined by the scope of the claims, not in the sense described above, and is intended to include all modifications within the scope and meaning equivalent to the scope of the claims.

What is claimed is:

1. A bias supply circuit comprising:
a bias supply terminal configured to supply a bias voltage to an amplifier;
a power supply terminal connected to a power supply;
a first inductor connected between the bias supply terminal and the power supply terminal;
a second inductor connected in series with the first inductor between the bias supply terminal and the power supply terminal, and connected between the first inductor and the power supply terminal;
a first node between the first inductor and the second inductor;
a first capacitor shunt-connected to the first node; and
a second node between the second inductor and the power supply terminal; and
a second capacitor shunt-connected to the second node.

2. The bias supply circuit according to claim 1, further comprising:
an output terminal configured to output a signal amplified by the amplifier; and
a third node between an output end of the amplifier and the output terminal;
wherein the bias supply terminal is connected to the third node, and
wherein the bias supply circuit includes a circuit between the bias supply terminal and the first inductor, the circuit being configured to reduce a leakage of the signal to the power supply terminal.

3. The bias supply circuit according to claim 1, further comprising:
a first resistor connected in parallel with the first inductor between the bias supply terminal and the first node; and
a second resistor connected in parallel with the second inductor between the first node and the second node.

4. The bias supply circuit according to claim 1,
wherein the first capacitor has a capacitance value smaller than a capacitance value of the second capacitor.

5. The bias supply circuit according to claim 1,
wherein the first inductor has an inductance smaller than an inductance of the second inductor.

6. The bias supply circuit according to claim 1, further comprising:
a third inductor connected in series with the first inductor and the second inductor between the bias supply terminal and the power supply terminal, the third inductor being connected between the first node and the second inductor;
a third node between the third inductor and the second inductor; and
a third capacitor shunt-connected to the third node.

7. The bias supply circuit according to claim 6, further comprising:
a first resistor connected in parallel with the first inductor between the bias supply terminal and the first node;
a second resistor connected in parallel with the second inductor between the third node and the second node; and
a third resistor connected in parallel with the third inductor between the first node and the third node.

8. An amplifier circuit comprising:
the bias supply circuit of claim 1; and
the amplifier.

9. The amplifier circuit according to claim 8,
wherein the amplifier is configured to perform a pulsed operation.

10. The amplifier circuit according to claim 8,
wherein the amplifier has a maximum output of 100 W or more.
